(19) United States
(12) Patent Application Publication
(10) Pub. No.: US 2016/0202119 A1
(43) Pub. Date: Jul. 14, 2016

(54) SPECTROMETER CHIP FOR ANALYZING FLUID SAMPLE AND METHOD OF MANUFACTURING THE SAME

(71) Applicant: SAMSUNG ELECTRONICS CO., LTD., Suwon-si (KR)

(72) Inventor: Juneyoung LEE, Seongnam-si (KR)

(73) Assignee: SAMSUNG ELECTRONICS CO., LTD., Suwon-si (KR)

(21) Appl. No.: 14/929,554

(22) Filed: Nov. 2, 2015

(30) Foreign Application Priority Data
Jan. 13, 2015 (KR) 10-2015-0006119

(51) Int. Cl. G01J 3/02; H01L 31/0352; H01L 31/18; G01J 3/42; G01J 3/44

(52) U.S. Cl. CPC G01J 3/0259; G01J 3/42; G01J 3/44; H01L 31/1804; H01L 31/0352

(57) ABSTRACT

A spectrometer chip for analyzing a fluid sample and a method of manufacturing the spectrometer chip are provided. The spectrometer chip includes a cell comprising a chamber in which the fluid sample is accommodated, and a spectrometer comprising a channel of silicon nitride, the channel being configured to resonate and transmit light that is emitted from the fluid sample, and the spectrometer being disposed on a surface of the cell. The spectrometer chip further includes a detector configured to detect the transmitted light.

### CROSS-REFERENCE TO RELATED APPLICATION

This application claims priority from Korean Patent Application No. 10-2015-0006119, filed on Jan. 13, 2015, in the Korean Intellectual Property Office, the disclosure of which is incorporated herein in its entirety by reference.

### BACKGROUND

1. Field

Apparatuses and methods consistent with exemplary embodiments relate to spectrometer chips for analyzing a fluid sample and methods of manufacturing the spectrometer chips.

2. Description of the Related Art

The average life span has increased owing to development in the medical science. Also, increase in people's interests in health and health management, as well as the development in the medical science, plays a role to increase the average life span.

An early diagnosis of a disease has increased owing to development of medical apparatuses, and small-sized medical apparatuses that are portable have been developed to check health states frequently. Such a small-sized medical apparatus may be applied to a mobile terminal to make people obtain more medical benefits.

A spectrometry may be used in the medical apparatuses. However, a spectrometer such as an absorption spectrometer or a Raman spectrometer is large in size, and thus, there is a limitation in applying a spectrometer to a portable medical apparatus.

### SUMMARY

Exemplary embodiments address at least the above problems and/or disadvantages and other disadvantages not described above. Also, the exemplary embodiments are not required to overcome the disadvantages described above, and may not overcome any of the problems described above.

One or more exemplary embodiments provide spectrometer chips capable of analyzing a fluid sample in an invasive manner.

One or more exemplary embodiments provide methods of manufacturing spectrometer chips having a small size and capable of analyzing a fluid sample.

According to an aspect of an exemplary embodiment, there is provided a spectrometer chip for analyzing a fluid sample, the spectrometer chip including a cell comprising a chamber in which the fluid sample is accommodated, and a spectrometer comprising a channel of silicon nitride, the channel being configured to resonate and transmit light that is emitted from the fluid sample, and the spectrometer being disposed on a surface of the cell. The spectrometer chip further includes a detector configured to detect the transmitted light.

The cell may be integrated on the spectrometer in a monolithic structure.

The cell may further include an inlet through which the fluid sample is injected into the chamber, and an outlet through which the fluid sample is discharged to outside the chamber.

The cell may include at least one among polydimethylsiloxane, quartz, and glass.

The spectrometer may include an absorption spectrometer or a Raman spectrometer.

The chamber may have a thickness of 0.1 μm to 103 μm.

The channel may include Si₃N₄.

The channel may include an input coupler configured to receive the emitted light, and an output coupler configured to output the light transmitted from the input coupler to the detector.

The chamber may be disposed on the input coupler, and is not disposed on the output coupler.

The output coupler may include holes.

The spectrometer may include a channel layer comprising silicon.

The spectrometer may include a channel layer comprising silicon dioxide.

According to an aspect of another exemplary embodiment, there is provided a method of manufacturing a spectrometer chip for analyzing a fluid sample, the method including forming a detector for detecting light, forming a first channel layer on the detector, and forming a silicon nitride layer on the first channel layer. The method further includes forming a spectrometer by patterning the silicon nitride layer, forming a second channel layer on the spectrometer, forming a cell by forming a chamber in a base, and bonding the cell to the second channel layer so that the chamber faces the second channel layer.

The forming the cell may include forming an inlet through which the fluid sample is injected into the chamber, and forming an outlet through which the fluid sample is discharged to outside the chamber.

The cell may include at least one among polydimethylsiloxane, quartz, and glass.

The chamber may have a thickness of 0.1 μm to 103 μm.

A channel may include Si₃N₄.

A channel may include through holes.

The first channel layer and the second channel layer may include silicon.

The first channel layer and the second channel layer may include silicon dioxide.

The bonding may be performed using a fusion bonding method or an anodic bonding method.

### BRIEF DESCRIPTION OF THE DRAWINGS

The above and/or other aspects will be more apparent by describing exemplary embodiments, with reference to the accompanying drawings, in which:

FIG. 1 is a schematic cross-sectional view of a spectrometer chip for analyzing a fluid sample, according to an exemplary embodiment;

FIG. 2 is a schematic cross-sectional view of a spectrometer chip for analyzing a fluid sample, according to another exemplary embodiment;

FIGS. 3, 4, and 5 are diagrams of a spectrometer adopted in a spectrometer chip for analyzing a fluid sample, according to exemplary embodiments;

FIG. 6 is a cross-sectional view of a spectrometer chip for analyzing a fluid sample, according to another exemplary embodiment;

FIGS. 7, 8, 9, 10, 11, and 12 are diagrams of a method of manufacturing a spectrometer chip for analyzing a fluid sample, according to an exemplary embodiment; and

FIGS. 13 and 14 are diagrams of a method of manufacturing a spectrometer chip for analyzing a fluid sample, according to another exemplary embodiment.

### DETAILED DESCRIPTION

Exemplary embodiments are described in greater detail below with reference to the accompanying drawings.

In the following description, like drawing reference numerals are used for like elements, even in different drawings. The matters defined in the description, such as detailed construction and elements, are provided to assist in a comprehensive understanding of the exemplary embodiments. However, it is apparent that the exemplary embodiments can be practiced without those specifically defined matters. Also, well-known functions or constructions may not be described in detail because they would obscure the description with unnecessary detail.

It will be understood that the terms “comprises” and/or “comprising” used herein specify the presence of stated features or components, but do not preclude the presence or addition of one or more other features or components.

In the following description, an expression such as “above” or “on” may include “on in a non-contact manner” as well as “directly on in a contact manner.” As used herein, the term “and/or” includes any and all combinations of one or more of the associated listed items. Expressions such as “at least one of,” when preceding a list of elements, modify the entire list of elements and do not modify the individual elements of the list.

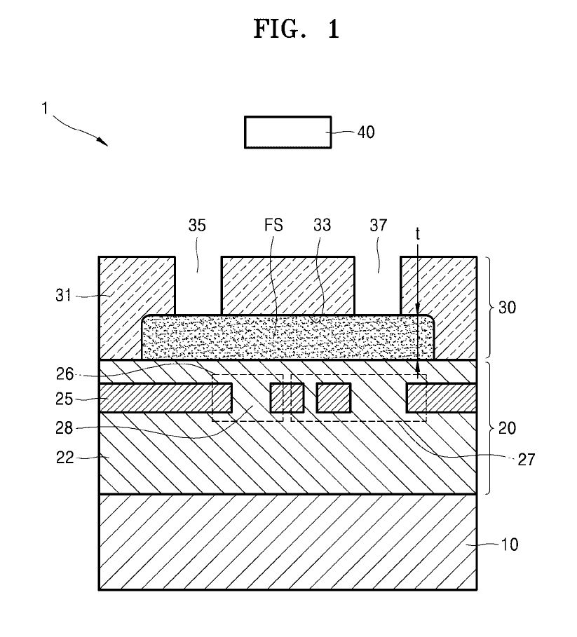

FIG. 1 is a schematic cross-sectional view of a spectrometer chip 1 for analyzing a fluid sample, according to an exemplary embodiment. The spectrometer chip 1 may include a cell 30 having a chamber 33, a spectrometer 20 disposed on a surface of the cell 30, and a detector 10 detecting light that has passed through the spectrometer 20. The cell 30 may include a base 31, and the chamber 33 is disposed in the base 31. The chamber 33 may accommodate a sample to be tested, for example, a fluid sample FS. The chamber 33 may have a constant thickness so that the fluid sample FS spreads in the chamber 33 to a uniform thickness. In addition, the chamber 33 may be thin so that the fluid sample FS may be loaded in the chamber 33 to be small in thickness. For example, the chamber 33 may have a thickness t ranging from about 0.1 μm to 103 μm. The cell 30 includes an injection hole 35 through which the fluid sample FS may be injected into the chamber 33, and an outlet 37 for discharging the fluid sample FS out of the chamber 33.

A light source 40 for irradiating light onto the chamber 33 may be disposed above the spectrometer chip 1. The light source 40 may irradiate, for example, an infrared ray, an ultraviolet (UV) ray, a visible ray, or a laser beam. The light source 40 may be disposed above the cell 30, and may be coupled to the cell 30.

The spectrometer 20 may include a channel layer 22 and a channel 25. The channel 25 may contain a silicon nitride-based material. For example, the channel 25 may be embedded in the channel layer 22. However, one or more exemplary embodiments are not limited thereto, that is, the channel 25 may be disposed between two channel layers having different media from each other.

The channel 25 may transmit light emitted from the fluid sample FS to be incident to the detector 10. The channel 25 may have a structure that may resonate the light emitted from the fluid sample FS to transmit light of a wavelength. The channel 25 may include an input coupler 26 to which the light emitted from the fluid sample FS is input, and an output coupler 27 outputting light of a wavelength from the light transmitted from the input coupler 26.

The input coupler 26 may receive light emitted from the fluid sample FS and guide the light to be transmitted to the output coupler 27. The input coupler 26 may have a structure that may improve an efficiency of coupling the light emitted from the fluid sample FS to the input coupler 26 without transmitting the light therethrough. For example, the input coupler 26 may have a nano-pattern. The nano-pattern may include, for example, an array of holes 28 having nano-sizes. However, one or more exemplary embodiments are not limited thereto.

The output coupler 27 may have a structure of resonating light of a wavelength. For example, the output coupler 27 may have a nano-pattern. The nano-pattern may have a structure, in which a plurality of holes is arranged. In FIG. 1, the nano-pattern has a structure in which through holes are arranged. The resonant wavelength may be adjusted by controlling sizes of the plurality of through holes, arrangement intervals of the plurality of through holes, and a length of the output coupler 27. However, the output coupler 27 is not limited thereto, but may have various structures. For example, the output coupler 27 may have a lattice structure. The resonant wavelength may be adjusted by controlling at least one selected from an interval between the lattice, a size of the lattice, a depth of the lattice, and the length of the output coupler 27.

If the nano-pattern includes a plurality of through holes, a material forming the channel layer 22 may be filled in the through holes. Otherwise, the material of the channel layer 22 may not be filled in the through holes, but the through holes may be filled only with air.

The channel 25 may include a silicon-based material. For example, the channel 25 may include a silicon nitride-based material, for example, Si₃N₄.

The spectrometer 20 may include a plurality of channels 25, and may split light by making the plurality of channels 25 outputs light of different wavelengths from each other. A configuration and arrangement of the plurality of channels 25 may be variously designed according to a wavelength band.

The spectrometer 20 may include, for example, an absorption spectrometer or a Raman spectrometer. If the spectrometer 20 is the absorption spectrometer, the spectrometer 20 may output an absorption spectrum. The absorption spectrometer may use the infrared ray, for example, near-infrared ray or mid-infrared ray. The absorption spectrometer may acquire an absorbance about an absorption frequency (or absorption wavelength) corresponding to the fluid sample FS from the absorption spectrum, and may obtain information about the fluid sample FS by using the absorbance.

If the spectrometer 20 includes the Raman spectrometer, the spectrometer 20 may output a Raman spectrum. The Raman spectrum may use, for example, a laser beam. The Raman spectrum is a spectrum of scattering light, and information about the fluid sample may be obtained from a distribution of the scattering light having a frequency that is different from that of the light incident to the fluid sample FS.

The detector 10 may detect the light that has passed through the spectrometer 20. The detector 10 may be, for example, an image sensor that may display light that has passed through the spectrometer 20 as an image. The detector 10 may include, for example, a photo diode array, a complementary metal oxide semiconductor (CMOS), or a charge coupled device (CCD). The detector 10 may be manufactured by using semiconductor processes. The detector 10, the spectrometer 20, and the cell 30 may be monolithically manufactured to have small sizes. That is, in an exemplary embodiment, the detector 10, the spectrometer 20, and the cell 30 may be integrated as a chip.

Hereinafter, operations of the spectrometer chip 1 will be described as follows. A sample to be checked is injected into the chamber 33 of the spectrometer chip 1. The sample may be a fluid sample FS. For example, the fluid sample FS may include blood, fluid, or a liquid sample. The sample may be a gas sample, as well as the fluid sample. The spectrometer chip 1 may be used for a medical usage, an industrial usage, or an experimental usage. Various methods may be used to inject the fluid sample FS in the spectrometer chip 1, for example, when the fluid sample FS is dropped onto the injection hole 35, the fluid sample FS may be dispersed to the chamber 33 due to a capillary phenomenon. When the dispersion of the fluid sample FS is finished, the fluid sample FS may be loaded in the chamber 33 to a uniform thickness. The fluid sample FS may be loaded depending on the size of the chamber 33. The loaded thickness of the fluid sample FS may be defined by a thickness of the chamber 33.

When the light source 40 irradiates light to the spectrometer chip 1, the light may be incident to the channel 25 after passing through the fluid sample FS. The light incident to the channel 25 is the light after interacting with the fluid sample FS, and has characteristics of the fluid sample FS. The light is coupled to the input coupler 26 of the channel 25, and may be transmitted from the input coupler 26 to the output coupler 27. The input coupler 26 may improve an optical efficiency by coupling the light irradiated from the light source 40 as much as possible. For example, a light incident area of the input coupler 26 may be increased to improve an optical coupling efficiency of the input coupler 26. An intensity of a signal detected by the detector 10 may be increased by increasing the optical efficiency in the input coupler 26.

The output coupler 27 may output light of a wavelength from the light transmitted from the input coupler 26 to the detector 10. That is, the output coupler 27 may split the light from the input coupler 26 and send the light to the detector 10. For example, the resonant wavelength may vary depending on the structure of the output coupler 27, and light having a wavelength band corresponding to the resonant wavelength may be split. The output coupler 27 may have, for example, a structure in which a plurality of holes is arranged. The resonant wavelength may vary depending on a size of the hole, an arrangement interval of the holes, and an entire length of the output coupler. The light output from the output coupler 27 is incident to the detector 10, and the detector 10 may detect a spectrum of the light. Physical and chemical characteristics or components of the fluid sample FS may be recognized by analyzing the spectrum of the light.

In an exemplary embodiment, the detector 10, the spectrometer 20, and the cell 30 may be integrated as a chip. For example, the cell 30 may be integrated in a monolithic structure at a side of a light input portion of the spectrometer 20 including the silicon nitride-based channel.

The light source 40 irradiating light may be disposed above the cell 30. The light source 40 may be disposed away from the cell 30, or may be integrated on the cell 30. For example, the light source 40 may be disposed on an upper surface of the cell 30. Otherwise, the light source 40 may be disposed on the input coupler 26 of the spectrometer. The light source 40 may include, for example, an infrared ray light source, an emission device, or a laser.

The cell 30 may further include the injection hole 35 and an outlet 37. The injection hole 35 is an inlet for injecting the fluid sample FS to the chamber 33, and the outlet 37 may discharge the fluid sample FS to outside of the chamber 33.

The base 31 of the cell 30 may include a material transmitting the light. The base 31 may include, for example, at least one selected from polydimethylsiloxane (PDMS), quartz, and glass.

The spectrometer chip 1 according to an exemplary embodiment may be manufactured to have a small size by integrating the cell 30 that may load the fluid sample FS with the spectrometer 20. The miniaturized spectrometer chip 1 may be portable and may be coupled to a mobile device. For example, when the spectrometer chip 1 is coupled to the mobile device, information about the sample detected by the spectrometer chip 1 may be stored in the mobile device. Otherwise, the information may be transmitted to a server of a hospital that a user of the mobile device uses via the mobile device so that a user's health may be managed via bi-directional communication. However, one or more exemplary embodiments are not limited thereto, application fields of the miniaturized spectrometer chip may be expanded.

Operations of the spectrometer chip 1 for analyzing the fluid sample FS will be described below.

The fluid sample FS is injected into the chamber 33 of the cell 30. The fluid sample FS flows into the chamber 33 and is distributed evenly. When the chamber 33 has a small and uniform thickness, the fluid sample FS may be loaded in the chamber 33 to a uniform thickness due to the capillary phenomenon. The light source 40 irradiates light to the cell 30. The light may be incident to the fluid sample FS after passing through the base 31. The light that has passed through the fluid sample FS is incident to the spectrometer 20, and the light of a wavelength band corresponding to the resonant wavelength of the channel 25 may be resonated. The light that has passed through the channel 25 may be detected by the detector 10. The light detected by the detector 10 may include information about the fluid sample FS.

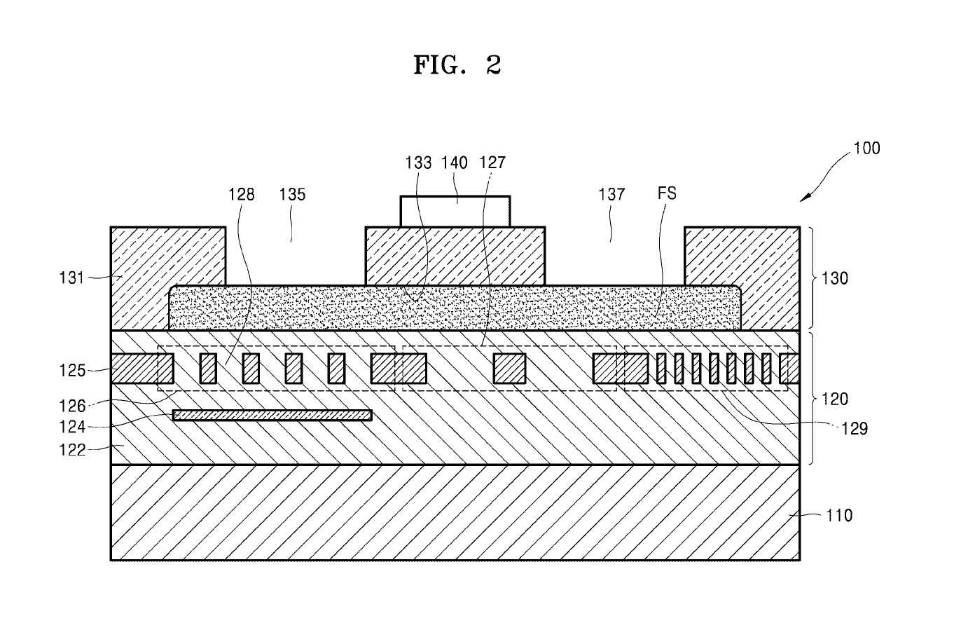

FIG. 2 is a schematic cross-sectional view of a spectrometer chip 100 for analyzing a fluid sample, according to another exemplary embodiment. The spectrometer chip 100 may include a cell 130 including a chamber 133, a spectrometer 120 having a channel 125 for guiding the light, and a detector 110 for detecting light that has passed through the spectrometer 120.

The chamber 133 may accommodate the fluid sample FS. The chamber 133 may make the fluid sample FS dispersed to a uniform and thin thickness in the chamber 133. The cell 130 may include an injection hole 135 through which the fluid sample FS may be injected to the chamber 133, and an outlet 137 for discharging the fluid sample FS to outside of the chamber 133.

A light source 140 irradiating light to the chamber 133 may be disposed. The light source 140 may irradiate, for example, an infrared ray, a UV ray, a visible ray, or a laser beam. The light source 140 may be provided above the cell 130, or may be coupled to the cell 130. For example, the light source 140 may be coupled to an upper surface of the cell 130. The cell 130 may be formed of a material transmitting the light.

The spectrometer 120 may include a channel layer 120 and the channel 125. The channel 125 may include a silicon nitride-based material. For example, the channel 125 may include Si₃N₄. The channel layer 122 may include silicon dioxide, for example, SiO₂. The channel 125 may include an input coupler 126 to which the light emitted from the fluid sample FS, and an output coupler 127 for outputting light of a wavelength from the light transmitted from the input coupler 126.

A reflector 124 for reflecting the light that has passed through holes 128 of the input coupler 126 may be further disposed under the input coupler 126. The light input to the input coupler 126 is transmitted to the output coupler 127. In addition, the more light is coupled to the input coupler 126, the more light is transmitted to the output coupler 127, and thereby improving the light efficiency. The light that is not coupled to the input coupler 126 is reflected by the reflector 124 to improve the coupling efficiency of the input coupler 126, and thus, the light efficiency may be also increased. The reflector 124 may include, for example, TiN. However, the reflector 124 is not limited to the above example, but may include various materials that reflect the light.

The channel 125 may further include a reflection pattern 129 on a location extending from the output coupler 127. The reflection pattern 129 may reflect the light that has passed through the output coupler 127 but is not output from the output coupler 127 to the detector 110 toward the output coupler 127 again. As such, the coupling effect of the output coupler 127 may be improved. The reflection pattern 129 may have a structure in which a plurality of holes are arranged, and may control a proceeding direction of the light according to at least one of a size and a structure the pattern.

Because the elements referred by the same reference numerals as those of FIG. 1 perform the same functions and operations as those of FIG. 1, detailed descriptions thereof are omitted here. The spectrometer chip 100 of FIG. 2 includes the reflector 124 to improve the efficiency of coupling the light to the input coupler 126. Also, the reflection pattern 129 may improve the efficiency of outputting the light from the output coupler 127 to the detector 110. As such, the intensity of the optical signal detected by the detector 110 may be increased.

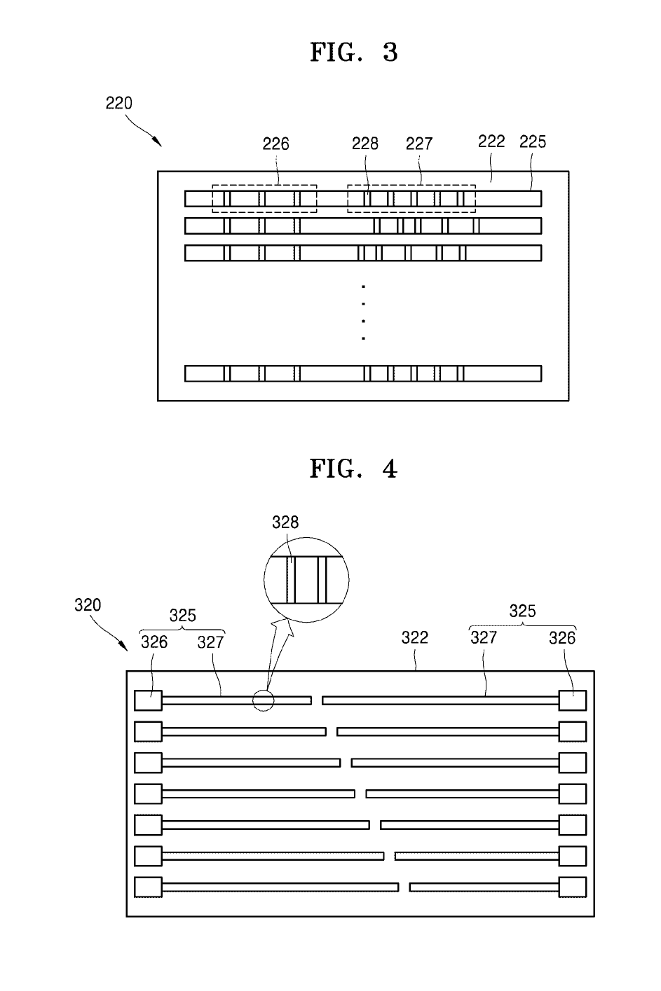

FIGS. 3, 4, and 5 are diagrams of a spectrometer adopted in a spectrometer chip for analyzing a fluid sample, according to exemplary embodiments. FIG. 3 is a plan view of a spectrometer 220, according to an exemplary embodiment. The spectrometer 220 may include a channel layer 222 and at least one channel 225 disposed in the channel layer 222. The at least one channel 225 may include an input coupler 226 to which the light is input, and an output coupler 227 outputting light of a wavelength from the light transmitted from the input coupler 226. If there is a plurality of channels 225, the plurality of channels 225 may be spaced apart from each other in parallel. Otherwise, the plurality of channels 225 may be arranged as a two-dimensional array in longitudinal and transverse directions of the channel layer 222. The plurality of channels 225 may include the output couplers 227 having different structures from each other. For example, the output coupler 227 may have a structure in which a plurality of holes 228 are arranged in the at least one channel 225, and the wavelength of the light output from the output coupler 227 may be adjusted by adjusting at least one selected from sizes of the holes 228, an interval of arranging the holes 228, and a length of the output coupler 227. That is, when the plurality of output couplers 227 has different structures from each other, the wavelengths of the light output from the plurality of output couplers 227 may be different from each other.

As shown in FIG. 3, the plurality of channels 225 are arranged, and the light input to the input coupler 226 may be split into beams having a plurality of wavelengths by the output couplers 227 having different structures from each other. As such, an optical spectrum of a wavelength band may be obtained.

FIG. 4 is a plan view of a spectrometer 320, according to another exemplary embodiment. The spectrometer 320 includes a channel layer 322 and at least one channel 325 disposed in the channel layer 322. The at least one channel 325 includes an input coupler 326 to which the light is input, and an output coupler 327 outputting light of a wavelength from the light transmitted from the input coupler 326. As shown in FIG. 4, two output couplers 327 having different lengths from each other may be arranged facing each other. At a side of the channel layer 322, the output couplers 327, lengths of which are gradually increased, may be arranged, and the other side of the channel layer 322, the output couplers 327, lengths of which are gradually reduced, may be arranged. The output coupler 327 may include a plurality of holes 328. For example, a wavelength of the light output from the output couplers 327 may vary depending on the length of the output coupler 327. Thus, a plurality of output couplers having the lengths shown in FIG. 4 may be provided to obtain a plurality of light beams having the same wavelength, and thus, an intensity of the light may be increased.

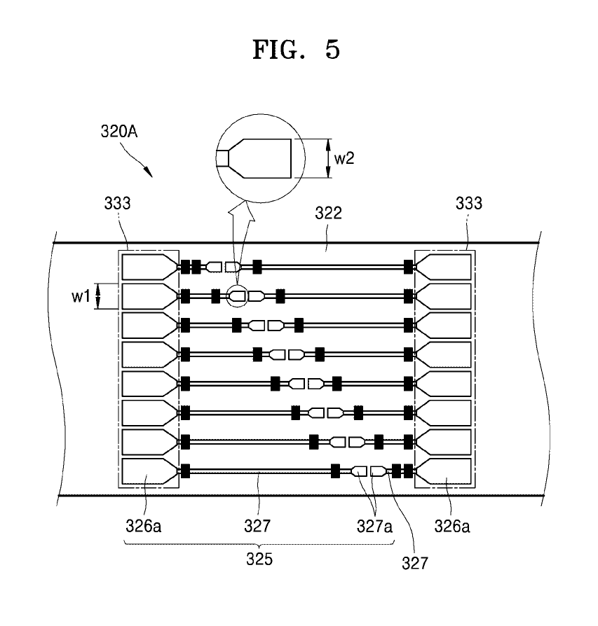

FIG. 5 is a plan view of a spectrometer 320A, according to another exemplary embodiment. The spectrometer 320A includes the channel layer 322 and at least one channel 325 disposed in the channel layer 322. The at least one channel 325 may include an input coupler 326a, to which the light is input, and an output coupler 327 for outputting light of a wavelength from the light transmitted from the input coupler 326a. The input coupler 326a may have a large incident surface, to which the light is incident, to receive the light as much as possible. For example, the input coupler 326a may have a width W that is greater than that of the output coupler 327, and the input coupler 326a may be tapered at a connection between the input coupler 326a and the output coupler 327. As such, an efficiency of coupling the light to the input coupler 326a may be improved.

In addition, the output couplers 327 may have different lengths from each other. Thus, the wavelength of the light output from the output coupler 327 may vary depending on the length of the output coupler 327. In addition, the output coupler 327 may have an output portion 327a having a width W2 that is greater than that of the other portion of the output coupler 327, at an end for outputting the light. Thus, the output ratio of the light may be improved.

In addition, an array of the input coupler 326a and the output coupler 327 shown in FIG. 5 may be repeatedly arranged.

Examples of the spectrometer 220, 320, and 320A are described above with reference to FIGS. 3, 4, and 5. The spectrometer 220, 320, or 320A and the cell 30 (see FIG. 1) may be integrated monolithically. In addition, when the cell 30 is integrated on the spectrometer 220, 320, or 320A, the chamber 33 of the cell 30 may be disposed at a side of the input coupler 226, 326, or 326a of the spectrometer 220, 320, or 320A. For example, referring to FIG. 5, a chamber 333 is disposed on the input coupler 326a and does not locate on the output coupler 327. Although the chamber 333 may be disposed to cover all the upper portions of the input coupler 326a and the output coupler 327, a volume of the chamber 333 may be reduced by being located only on the input coupler 326a so that an amount of the fluid sample FS may be reduced and a time taken for loading the fluid sample FS in the chamber 333 may be also reduced. That is, the chamber 333 may be disposed facing the input coupler 326a.

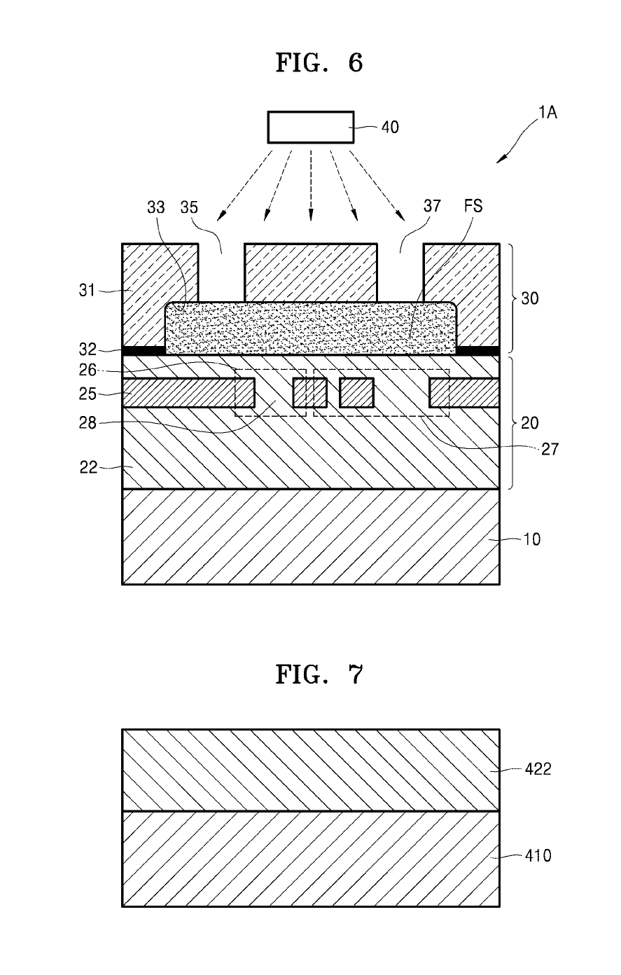

FIG. 6 is a schematic cross-sectional view of a spectrometer chip 1A for analyzing a fluid sample, according to another exemplary embodiment. The spectrometer chip 1A may include the cell 30 having the chamber 33, the spectrometer 20 disposed on a surface of the cell 30 and including the channel 25, and the detector 10 for detecting light that has passed through the spectrometer 20. The cell 30, the spectrometer 20, and the detector 10 are already described above with reference to FIG. 1, and thus, detailed descriptions thereof are omitted here. When comparing the spectrometer chip 1A with the spectrometer chip 1 of FIG. 1, an adhesive layer 32 is further disposed between the base 31 of the cell 30 and the channel layer 22. The adhesive layer 32 may include, for example, amorphous silicon. The base 31 may include, for example, glass. When the base 31 includes the glass, the cell 30 and the spectrometer 20 may be attached to each other by an anodic bonding of the adhesive layer 32.

Hereinafter, a method of manufacturing a spectrometer chip according to an exemplary embodiment will be described below.

FIGS. 7, 8, 9, 10, 11, and 12 are diagrams of a method of manufacturing a spectrometer chip for analyzing a fluid sample, according to an exemplary embodiment. Referring to FIG. 7, a first channel layer 422 may be formed on a detector 410. The detector 410 may be manufactured to have various shapes through semiconductor processes. The detector 410 may include, for example, a photo diode array, a CMOS, or a CCD.

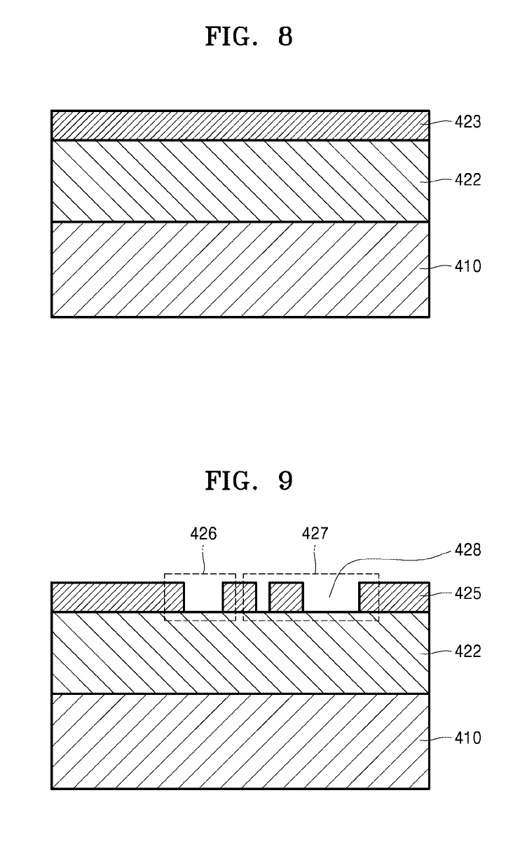

Referring to FIG. 8, a silicon nitride-based layer 423 may be stacked on the first channel layer 422. The silicon nitride-based layer 423 may include, for example, Si₃N₄.

Referring to FIG. 9, a pattern 428 is formed in the silicon nitride-based layer 423 to form a channel 425. The channel 425 may include an input coupler 426 and an output coupler 427. The channel 425 may be formed in various shapes, for example, the channel 425 may include a plurality of through holes penetrating through the silicon nitride-based layer with various intervals. For example, a resonant wavelength band may vary depending on a width of the through hole and the interval between the through holes. Otherwise, the resonant wavelength band may also vary depending on a length of the output coupler 427.

Referring to FIG. 10, a second channel layer 429 may be formed on the channel 425. The first channel layer 422 and the second channel layer 429 may be formed of the same material. Alternatively, the first channel layer 422 and the second channel layer 429 may be formed of different materials from each other. For example, the first channel layer 422 and the second channel layer 429 may include a silicon-based material, for example, SiO₂.

The second channel layer 429 may be filled in the pattern 428. However, one or more exemplary embodiments are not limited thereto, and the second channel layer 429 may be stacked on the pattern 428 without filling the pattern 428.

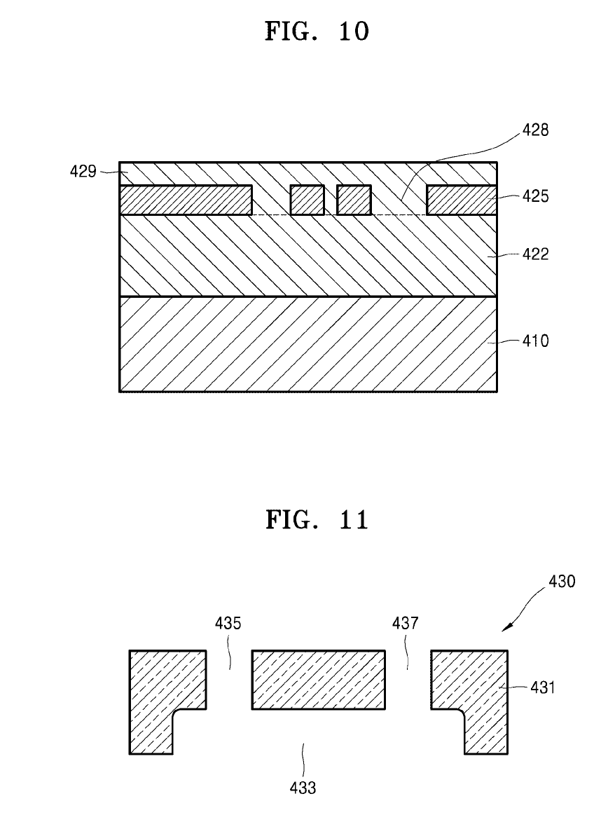

Referring to FIG. 11, a cell 430 may be formed by forming a chamber 433 in a base 431. The base 431 may include at least one selected from the PDMS, quartz, and glass. An inlet 435 and an outlet 437 connected to the chamber 433 may be further formed.

Referring to FIG. 12, the base 431 may be bonded to the second channel layer 429 shown in FIG. 10. Before bonding the base 431 onto the second channel layer 429, surfaces of the base 431 and the second channel layer 429 may be treated by plasma/ozone. As such, a coupling force may be increased when the base 431 is bonded to the second channel layer 429. The bonding may be performed by using a fusion bonding method or an anodic bonding method. As described above, the cell 430 is integrated monolithically with the channel layer including the channel 425, and thus, a spectrometer chip of a small size may be manufactured.

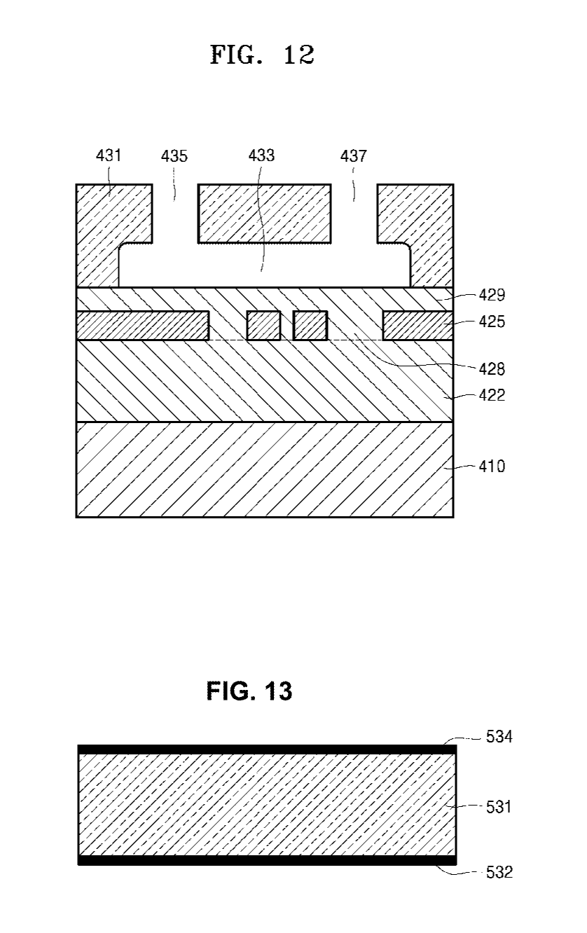

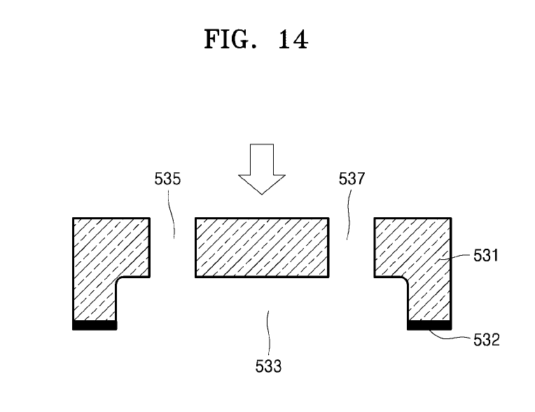

FIGS. 13 and 14 are diagrams of a method of manufacturing a spectrometer chip for analyzing a fluid sample, according to another exemplary embodiment. FIG. 13 shows a case in which a base 531 is formed of glass. A first layer 532 may be formed on a surface of the base 531 formed of the glass, and a second layer 534 may be stacked on the other surface of the base 531. The first layer 532 and the second layer 534 may include, for example, polysilicon.

Referring to FIG. 14, the first layer 532 is patterned, and the base 531 is etched through semiconductor processes to form a chamber 533. The first layer 532 remains on a region other than the region where the chamber 533 is formed. Here, an inlet 535 and an outlet 537 may be further formed. The second layer 534 may be removed. The base 531 may be bonded onto the second channel layer 429 (see FIG. 10) so that the first layer 532 that remains faces the second channel layer 429.

As described above, the cell including the chamber is bonded onto the detector and the spectrometer integrated through the semiconductor processes to manufacture a spectrometer chip having an on-chip structure.

The foregoing exemplary embodiments are examples and are not to be construed as limiting. The present teaching can be readily applied to other types of apparatuses. Also, the description of the exemplary embodiments is intended to be illustrative, and not to limit the scope of the claims, and many alternatives, modifications, and variations will be apparent to those skilled in the art.

What is claimed is:

1. A spectrometer chip for analyzing a fluid sample, the spectrometer chip comprising:
a cell comprising a chamber in which the fluid sample is accommodated;
a spectrometer comprising a channel of silicon nitride, the channel being configured to resonate and transmit light that is emitted from the fluid sample through the spectrometer, and the spectrometer being disposed on a surface of the cell; and
a detector configured to detect the transmitted light.

2. The spectrometer chip of claim 1, wherein the cell is integrated on the spectrometer in a monolithic structure.

3. The spectrometer chip of claim 1, wherein the cell further comprises:
an inlet through which the fluid sample is injected into the chamber; and
an outlet through which the fluid sample is discharged to outside the chamber.

4. The spectrometer chip of claim 1, wherein the cell comprises at least one among polydimethylsiloxane, quartz, and glass.

5. The spectrometer chip of claim 1, wherein the spectrometer comprises an absorption spectrometer or a Raman spectrometer.

6. The spectrometer chip of claim 1, wherein the chamber has a thickness of 0.1 μm to 103 μm.

7. The spectrometer chip of claim 1, wherein the channel comprises Si₃N₄.

8. The spectrometer chip of claim 1, wherein the channel comprises:
an input coupler configured to receive the emitted light; and
an output coupler configured to output the light transmitted from the input coupler to the detector.

9. The spectrometer chip of claim 8, wherein the chamber is disposed on the input coupler, and is not disposed on the output coupler.

10. The spectrometer chip of claim 8, wherein the output coupler comprises holes.

11. The spectrometer chip of claim 1, wherein the spectrometer comprises a channel layer comprising silicon.

12. The spectrometer chip of claim 1, wherein the spectrometer comprises a channel layer comprising silicon dioxide.

13. A method of manufacturing a spectrometer chip for analyzing a fluid sample, the method comprising:
forming a detector for detecting light;
forming a first channel layer on the detector;
forming a silicon nitride layer on the first channel layer;
forming a spectrometer by patterning the silicon nitride layer;
forming a second channel layer on the spectrometer;
forming a cell by forming a chamber in a base; and
bonding the cell to the second channel layer so that the chamber faces the second channel layer.

14. The method of claim 13, wherein the forming the cell comprises:
forming an inlet through which the fluid sample is injected into the chamber; and
forming an outlet through which the fluid sample is discharged to outside the chamber.

15. The method of claim 13, wherein the cell comprises at least one among polydimethylsiloxane, quartz, and glass.

16. The method of claim 13, wherein the chamber has a thickness of 0.1 μm to 103 μm.

17. The method of claim 13, wherein a channel comprises Si₃N₄.

18. The method of claim 13, wherein a channel comprises through holes.

19. The method of claim 13, wherein the first channel layer and the second channel layer comprise silicon.

20. The method of claim 13, wherein the first channel layer and the second channel layer comprise silicon dioxide.

21. The method of claim 13, wherein the bonding is performed using a fusion bonding method or an anodic bonding method.
